(19) United States
(12) Patent Application Publication
(10) Pub. No.: US 2026/0128253 A1
(43) Pub. Date: May 7, 2026

(54) SYSTEM AND METHOD FOR HIGH ANGLE ION BEAM

(71) Applicant: Applied Materials, Inc., Santa Clara, CA (US)

(72) Inventors: Costel Biloiu, Rockport, MA (US); Alexander S. Perel, Danvers, MA (US); Alexandre Likhanskii, Malden, MA (US); Kevin T. Ryan, Wilmington, MA (US); Daniel Distaso, Rowley, MA (US); Kevin M. Daniels, Lynnfield, MA (US); Christopher Campbell, Newburyport, MA (US)

(73) Assignee: Applied Materials, Inc., Santa Clara, CA (US)

(21) Appl. No.: 18/937,903

(22) Filed: Nov. 5, 2024

(51) Int. Cl. H01J 37/08

(52) U.S. Cl. CPC H01J 37/08; H01J 2237/04735

(57) ABSTRACT

A processing system may include a plasma chamber operable to generate a plasma, and an extraction assembly, arranged along a side of the plasma chamber. The extraction assembly may include a screen plate, disposed immediately adjacent to the side of the plasma chamber, the screen plate having an angled portion that comprises a screen aperture, to extract an angled ion beam towards a first end of the extraction assembly.

The extraction assembly may also include an acceleration plate, disposed outside of the screen plate, the acceleration plate having a middle portion that is shaped according to an outer surface of the screen plate. As such, the acceleration plate may include an acceleration aperture, aligned with the screen aperture, and the acceleration plate may include a distal portion adjacent to the middle portion, the distal portion having a distal end that extends beyond an end of the screen plate.

### FIELD OF THE DISCLOSURE

The present embodiments relate to a processing apparatus, and more particularly, to an apparatus enabling ion extraction from a plasma at high on-substrate incidence angle.

### BACKGROUND OF THE DISCLOSURE

Known apparatus used to treat substrates with ions include beamline ion implanters and plasma immersion ion implantation tools. These approaches are useful for treating substrates with ions over a range of energies. In beamline ion implanters, ions are extracted from a source, mass analyzed and then transported to the substrate surface. In plasma immersion ion implantation apparatus, a substrate is located in the same chamber while the plasma is generated adjacent to the plasma. The substrate is set at negative potential with respect to the plasma, and positive ions crossing the plasma sheath in front of the substrate may impinge on the substrate perpendicularly (at a zero incidence angle).

Many of such approaches employ perpendicular incidence on a substrate or wafer, while other applications employ angled etching such as controlled etching of trench sidewalls, hole elongation, photoresist shrinking, line edge roughness (LER)/line width roughness (LWR) improvement, and magnetic random memory structures etching, where ion beams are defined by a non-zero mean angle of incidence with respect to the perpendicular to the substrate. Control of such processes may be more difficult than control of ion beam processing at normal incidence. Some high angle of incidence approaches suffer from a limited incidence angle, and high glitching rates, for instance.

It is with respect to these and other considerations, the present disclosure is provided.

### SUMMARY

In one embodiment, a processing system is provided. The processing system may include a plasma chamber operable to generate a plasma, and an extraction assembly, arranged along a side of the plasma chamber. The extraction assembly may include a screen plate, disposed immediately adjacent to the side of the plasma chamber, the screen plate having an angled portion that comprises a screen aperture, to extract an angled ion beam towards a first end of the extraction assembly. The extraction assembly may also include an acceleration plate, disposed outside of the screen plate, the acceleration plate having a middle portion that is shaped according to an outer surface of the screen plate. As such, the acceleration plate may include an acceleration aperture, aligned with the screen aperture, and the acceleration plate may include a distal portion adjacent to the middle portion, the distal portion having a distal end that extends beyond an end of the screen plate.

In another embodiment, a method of processing a substrate is provided. The method may include generating a plasma in a plasma chamber, and extracting an angled ion beam from the plasma chamber through an extraction assembly. The extraction assembly may include a screen plate, having an angled portion that has a screen aperture, to extract the angled ion beam towards a first end of the extraction assembly. The extraction assembly may also include an acceleration plate, having a middle portion that is shaped according to an outer surface of the screen plate, and having an acceleration aperture, aligned with the screen aperture. The method may further include directing the angled ion beam to the substrate, wherein the angled ion beam does not overlap a set of electric filed lines that are generated by the extraction assembly.

### BRIEF DESCRIPTION OF THE DRAWINGS

The accompanying drawings illustrate exemplary approaches of the disclosed embodiments so far devised for the practical application of the principles thereof.

FIG. 1 shows a block diagram of a processing apparatus including a high angle extraction assembly in accordance with various embodiments of the disclosure;

FIG. 2A shows a computer simulation in side cross-sectional view of a variant of an extraction assembly of the processing apparatus of FIG. 1, during ion beam extraction, in accordance with various embodiments of the disclosure;

FIG. 2B shows a computer simulation in side cross-sectional view of another variant of an extraction assembly of the processing apparatus of FIG. 1, during ion beam extraction, in accordance with various embodiments of the disclosure;

FIG. 2C shows a computer simulation in side cross-sectional view of a further variant of an extraction assembly of the processing apparatus of FIG. 1, during ion beam extraction, in accordance with various embodiments of the disclosure;

FIG. 3A shows a computer simulation in side cross-sectional view of a variant of an extraction assembly of FIG. 2A, during ion beam extraction, showing ion trajectories and electric field lines, in accordance with various embodiments of the disclosure;

FIG. 3B shows a computer simulation of the scenario of FIG. 3A, showing secondary electrons trajectories;

FIG. 3C shows a computer simulation in side cross-sectional view of a variant of an extraction assembly of FIG. 2C, during ion beam extraction, in accordance with various embodiments of the disclosure;

FIG. 3D shows a close-up view of the arrangement of FIG. 3A;

FIG. 4A shows a perspective view of an extraction optics, in accordance with embodiments of the present disclosure;

FIG. 4B shows an exploded view of the extraction optics of FIG. 4A;

FIG. 5A shows a top tilted view of a screen plate, in accordance with some embodiments;

FIG. 5B shows a bottom tilted view of the screen plate of FIG. 5A;

FIG. 5C shows a top perspective view of the screen plate of FIG. 5A;

FIG. 6A shows a top tilted view of an acceleration plate, in accordance with some embodiments;

FIG. 6B shows a bottom tilted view of the acceleration plate of FIG. 6A;

FIG. 6C shows a top perspective view of the acceleration plate of FIG. 6A;

FIG. 6D shows a top tilted view of an acceleration plate, in accordance with additional embodiments;

FIG. 7A shows a computer simulation in side cross-sectional view of a variant of an extraction assembly of FIG. 2C, during ion beam extraction, in accordance with various embodiments of the disclosure;

FIG. 7B is a graph showing the ion beam current density as a function of beam angle for the scenario of FIG. 7A;

FIG. 7C is a graph showing the ion beam angle as a function of position on a substrate for the scenario of FIG. 7A;

FIG. 8A shows a top tilted view of another acceleration plate, in accordance with some embodiments;

FIG. 8B shows a bottom tilted view of the acceleration plate of FIG. 8A;

FIG. 8C shows a top perspective view of the acceleration plate of FIG. 8A;

FIG. 9A shows a top and side view of exemplary perforated plate configurations;

FIG. 9B depicts a composite view of the perforated plate configurations and associated electric field under a first extraction voltage;

FIG. 9C depicts a composite view of the perforated plate configurations and associated electric field under a second extraction voltage;

FIG. 9D depicts a composite view of the perforated plate configurations and associated electric field under a third extraction voltage;

FIG. 9E depicts a composite view of the perforated plate configurations and associated electric field under a first plate thickness at a given extraction voltage;

FIG. 9F depicts a composite view of the perforated plate configurations and associated electric field under a second plate thickness at a given extraction voltage;

FIG. 9G depicts a composite view of the perforated plate configurations and associated electric field under a third plate thickness at a given extraction voltage; and

FIG. 10 depicts an exemplary process flow.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true”cross-sectional view, for illustrative clarity. Furthermore, for clarity, some reference numbers may be omitted in certain drawings.

### DETAILED DESCRIPTION

Methods, apparatuses, and systems including high angle extraction optics are disclosed in accordance with the present disclosure and with reference to the accompanying drawings, where embodiments are shown. The embodiments may be embodied in many different forms and are not to be construed as being limited to those set forth herein. Instead, these embodiments are provided so the disclosure will be thorough and complete, and will fully convey the scope of methods, systems, and devices to those skilled in the art.

In various embodiments, extraction optics, also referred to as extraction assemblies, are provided to generate high angle of incidence (“high angle”) ion beams from a plasma-type ion source. Such extraction assemblies are suitable for use in compact ion beam processing apparatus, where a substrate is maintained in close proximity to a plasma chamber from which chamber an ion beam is extracted. The substrate may be located in a housing or processing chamber, adjacent the plasma chamber, and in communication with a plasma in the plasma chamber through the extraction assembly.

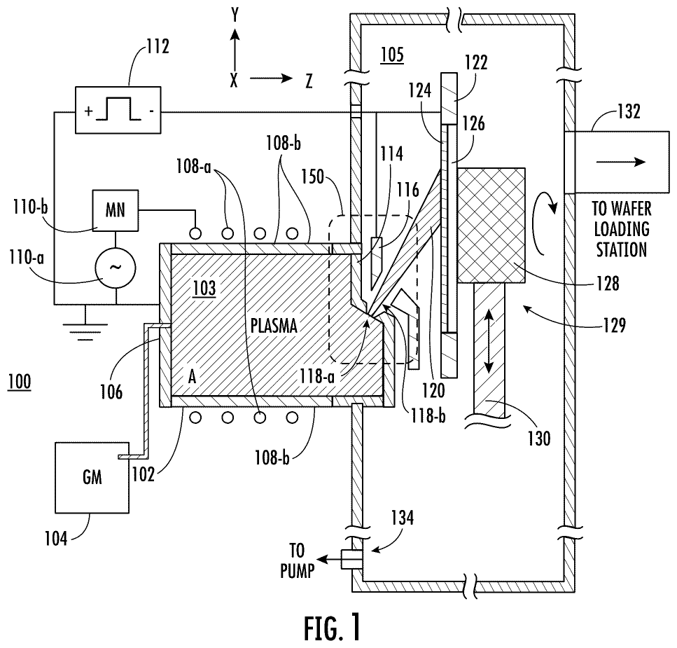

FIG. 1 depicts a system or processing apparatus 100, in accordance with embodiments of this disclosure. The processing apparatus 100 includes a plasma source comprised of a plasma chamber 102 to generate a plasma 103 therein. The plasma chamber 102 may function as part of a plasma source such as an RF inductively-coupled plasma (ICP) source, capacitively coupled plasma (CCP) source, helicon source, electron cyclotron resonance (ECR) source), indirectly heated cathode (IHC) source, glow discharge source, or other plasma sources known to those skilled in the art. In this particular embodiment, the plasma source is an ICP source where the power is coupled into the plasma through an RF generator 110-a—matching network 110-b tandem arrangement. The transfer of the RF power from the RF generator 110-a to the gas atoms and/or molecules takes places through an antenna 108-a and a dielectric window 108-b.

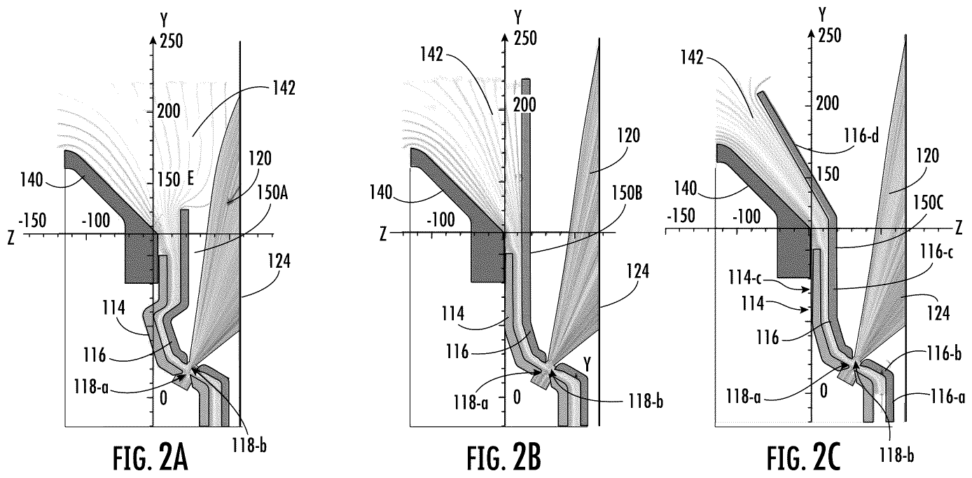

As known in the art, a gas manifold (not shown) may be connected to the plasma chamber 102 through appropriate gas lines and gas inlets. The plasma chamber 102 or other components of the processing apparatus 100 also may be connected to a vacuum system (not shown), such as a turbo molecular pump backed by a rotary or membrane pump. The plasma chamber 102 is defined by chamber walls, where at least a portion of the plasma chamber 102 may include an enclosure 140 (see FIG. 2A) that is electrically conductive. The plasma chamber 102 may be arranged adjacent to a process chamber 105. The process chamber 105 may include a substrate holder assembly 129 (or, simply, “substrate holder’) that includes a platen 126 and insert 122, in one non-limiting embodiment, where a substrate 124 is arranged on the platen 126, and surrounded by the insert 122. The substrate holder assembly 129 may further include a substrate stage or set of substrate stages, including a rotational stage 128 and translation stage 130.

In some embodiments, the plasma chamber 102 may be electrically insulated from the process chamber 105 and biased with respect to the process chamber 105 using a bias voltage supply 112. For example, the plasma chamber 102 may be held at elevated voltage, such as +1000 V, while the substrate 124, the platen 126, insert 122, and process chamber 105 are grounded. Alternatively, the combination of substrate 124/platen 126/insert 122 may be held at negative potential, while the plasma chamber 102 and processing chamber 105 are grounded. In one example, the bias voltage supply 112 may be a pulsed DC voltage supply, as known in the art.

The processing apparatus 100 may include an extraction assembly 150 that includes a screen plate 114 and acceleration plate 116. The screen plate 114 is disposed immediately adjacent to the side of the plasma chamber 102. The screen plate 114 may be formed of an electrically conductive material such as a metal, and may be directly attached to a conductive wall of the plasma chamber 102 in some embodiments. The acceleration plate 116 is disposed outside of the screen plate 114, as shown. As detailed in the embodiments to follow, the screen plate 114 is non-planar and includes an angled portion that has a screen aperture 118-a that defines an angled ion beam 120, and serves to direct the angled ion beam 120 to the substrate 124, in conjunction with an acceleration aperture 118-b of acceleration plate 116. As shown, the angled ion beam 120 is directed toward one end of the extraction assembly 150, in this case, towards the top of the figure. As detailed with respect to the embodiments to follow, a given portion of the acceleration plate 116 may be shaped according to the outer surface of the screen plate 114, while another portion of the acceleration plate 116 may extend beyond the screen plate 114.

The extraction apertures formed in the extraction assembly 150 and other embodiments of extraction apertures to follow may form an elongated aperture(s), having a long axis extending along a first direction, in this case, along the X-axis. In other words, the extraction apertures may be narrow along one direction, such as on the order of a few millimeters, several millimeters, or so, while elongated along a second direction, such as on the order of tens of centimeters. In these scenarios, positive ions may be extracted from the plasma 103 and directed to the substrate 124 at an ion energy proportionate to the difference in voltage between the plasma chamber 102 and the substrate holder assembly 129. The extraction apertures 118a and 118b may be arranged at angled sections of the screen plate 114 and acceleration plate 116 so that the ion beam 120 defines a high angle of incidence (α) with respect to a perpendicular to a plane of the substrate 124. Examples of suitable values for α are between 40 degrees and 85 degrees according to various non-limiting embodiments.

As shown in FIG. 1, the translation stage 130 may be movable along a first direction, parallel to the side (X-Y plane) of the plasma chamber 102. In the example, shown, the translation stage 130 may be movable along the Y-axis. As such, the substrate 124 may be scanned along a given scan direction, such as the Y-axis to intercept the ion beams 120, so that most or all portions of the substrate 124 are treated by the ion beam 120. Thus, during one mode of operation, during processing, the substrate is scanned up and down parallel to the Y-axis. The scanning may be performed at a constant velocity with respect to a stationary status of the extraction assembly 150. In this fashion, an entirety of the surface of the substrate 124 may be exposed to the ion beam 120. For a given scanning speed, the number of passes of the substrate 124 with respect to ion beam 120 may be calculated based on a required ion dose and available ion beam current. For the purposes of illustration, taking a scanning speed of the substrate of 10 cm/s and an ion beam height (along the Y-axis) of 30 mm at the substrate plane, the time spent by any substrate surface under ion bombardment is 300 milliseconds. Given an exemplary pulsing frequency of 40 kHz and a duty cycle of 50% of a pulsed extraction voltage generated by bias voltage supply 112, the surface of the substrate 124 is exposed to approximatively 6,000 cycles of ion bombardment while passing in front of the extraction assembly 150.

Note that when the ion beam 120 is used as an etching ion beam, the etch rate for material of the substrate 124 is a complex function of ion energy, ion flux, ion incidence angle, and the nature of the material to be etched. High etch uniformity is accomplished with a rotational stage 128, which stage may allow substrate rotation in increments of 0.1° over a full 360°. Depending on the materials to be etched and the pattern of structures on the surface of the substrate 124, just one rotation of the substrate 124 (of 180°) may be sufficient to obtain etch uniformity better than 1%. For a given process requirement, the exact construction of the extraction assembly 150 may be adjusted to obtain necessary ion beam characteristics, such as beam energy of ion beam 120, mean angle of incidence of the ion beam 120, and angular spread of the ion beam 120.

In particular embodiments, where the ion beam 120 is generated for reactive ion beam etching of the substrate 124, reactive plasma species may be generated in the plasma chamber 102 by introducing a mixture of gasses such as fluorocarbons (CF₄, C₂F₆, C₃F₈), fluorinated hydrocarbons (CHF₃, CH₃F) mixed with Ar, O₂, H₂, N₂ through gas inlet baffle 106. Reacted gases are pumped away from the plasma chamber 102 through the extraction aperture 118-a and extraction aperture 118-b, the gap between the acceleration plate 116 and the insert 122/platen 126, using a pump, not shown. One use for the insert 122 is to provide a wider and taller structure around the substrate 126 at the substrate plane (X-Y plane) to assure a constant gas pressure in the process chamber 105 while scanning the substrate 124 up and down in the front of the extraction assembly 150. Volatile etch byproducts resulting from the interaction of the ion beam 120 and radicals with the substrate surface may follow the same pumping path, i.e., from the gap between the extraction assembly 150 and the substrate 124 through the process chamber 105 to the pump.

FIGS. 2A-2C show variants of the extraction assembly of FIG. 1, where a screen plate and acceleration plate both have a non-planar structure. The screen plates in particular may define a staggered structure that is characterized by a first portion, disposed away from the plasma chamber, and disposed along a first edge of an angled portion; and a second portion, disposed along a second edge of the angled portion, and immediately adjacent to the plasma chamber.

In particular, FIG. 2A shows a computer simulation in side cross-sectional view of a variant of an extraction assembly of the processing apparatus of FIG. 1, during ion beam extraction, in accordance with various embodiments of the disclosure. In this example, the extraction assembly 150A includes a pocket shaped variant of the screen plate 114 and the acceleration plate 116.

The acceleration plate 116 in this configuration extends just slightly beyond the end of the screen plate 114 in the Y-direction. In this configuration, an ion beam 120 is extracted at an ion energy of 1 kV. The separation between the acceleration plate 116 and substrate 124 is 6 mm. As a result, the ion beam 120 impacts the substrate 124 over a beam propagation region that extends approximately 200 mm along the Y direction, at the substrate plane. As shown, the propagation regions the electrostatic field lines 142 leak into the beam propagation region (the region between the acceleration plate 116 and the substrate 124), causing a distortion of the ion beam 120. As a result, the trajectories of the ions in the upper portion of the ion beam 120 are bent, reducing the maximum beam angle of incidence on the substrate 124.

FIG. 2B shows a computer simulation in side cross-sectional view of another variant of an extraction assembly of the processing apparatus of FIG. 1, during ion beam extraction, in accordance with various embodiments of the disclosure. In this embodiment, there is not a pocket structure for the extraction assembly 150B. In this configuration, the variant of acceleration plate 116 extends beyond the end of the screen plate substantially, in the exact simulation, approximately 150 mm, while the separation between screen plate 114 and acceleration plate 116 along the Z-axis is just 8 mm. Because the acceleration plate is taller along the Y-axis a screening of the beam propagation region from the electrostatic field lines 142 occurs, and the ions of ion beam 120 travel unperturbed to the substrate 124. However, for this configuration, a pumping of the etching byproducts released from the substrate surface of substrate 124 is more constricted, because of the smaller vacuum conductance, as compared to the configuration of FIG. 2A.

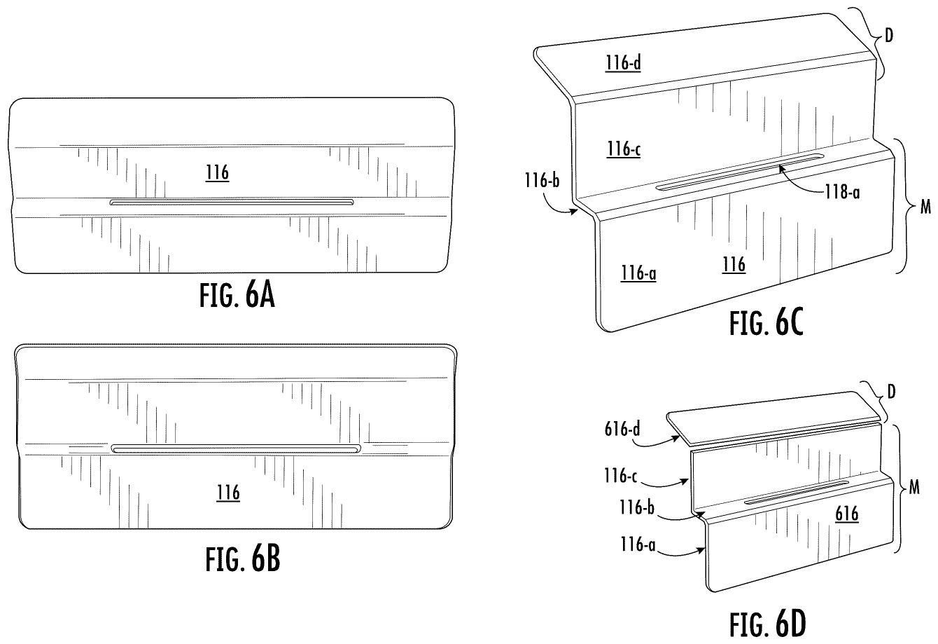

FIG. 2C shows a computer simulation in side cross-sectional view of a further variant of an extraction assembly of the processing apparatus of FIG. 1, during ion beam extraction, in accordance with various embodiments of the disclosure. In this configuration, an extraction assembly 150C includes a variant of the acceleration plate 116 that includes several different sections. With reference also to FIG. 6C, discussed further below, the variant of the acceleration plate 116 in this illustration may include a first section 116a, aligned over a first portion of the screen plate 114, meaning over the portion of the screen plate 114 that is furthest away from the enclosure 140 of the plasma chamber 102. The acceleration plate 116 further includes a first angled section 116-b, having a first edge, adjacent to the first section 116a, and containing an angled aperture that is represented by aperture 118-b (see FIG. 2C). The acceleration plate 116 also includes a second section 116-c, having an inner edge adjacent to a second edge of the first angled section 116-b, and extending over a second portion 114-c of the screen plate 114 that is attached to the enclosure 140. Note that the second section 116-b extends beyond an end of the second portion 114-c. The acceleration plate 116 in this variant also comprises a second angled section 116-d, disposed adjacent to an outer edge of the second section 116-c, and is angled toward the enclosure 140 of the plasma chamber 102. In particular, as shown in the embodiments of FIGS. 2A-2C the plasma chamber 102 may have an angled side region as shown in the portion of the enclosure 140 that forms a non-zero angle with respect to the Z-axis and Y-axis. The second angled section 116-d may be angled to match or approximately match the angled side region (meaning the shape of the enclosure 140 of the plasma chamber in this embodiment so as to be angled away from the surface of the substrate 124. As a consequence, in this variant, the acceleration plate 116 electrostatically screens the electrostatic field lines 142 from the ion beam 120 and also improves the pumping in the gap between the acceleration plate 116 and the substrate 124.

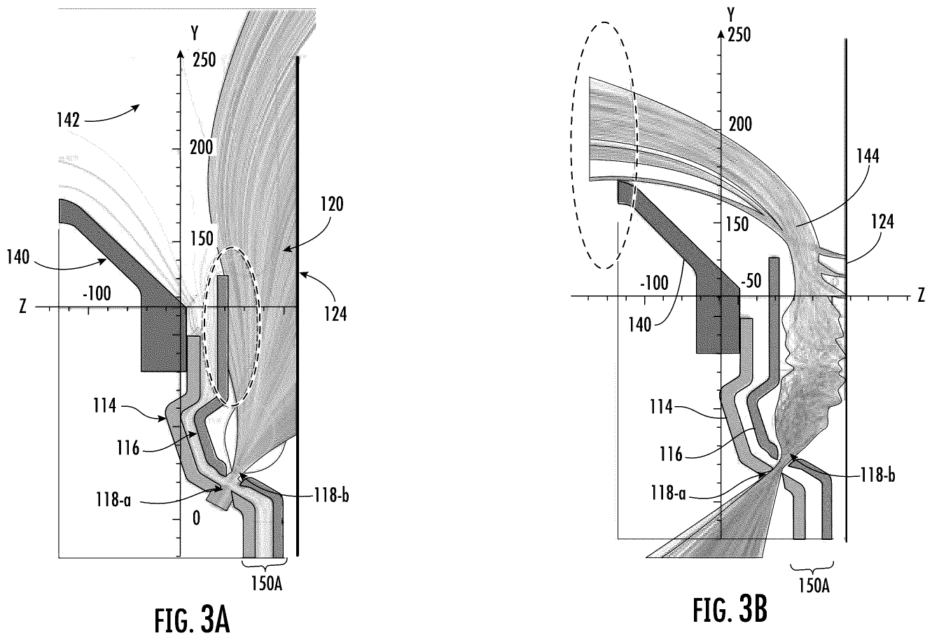

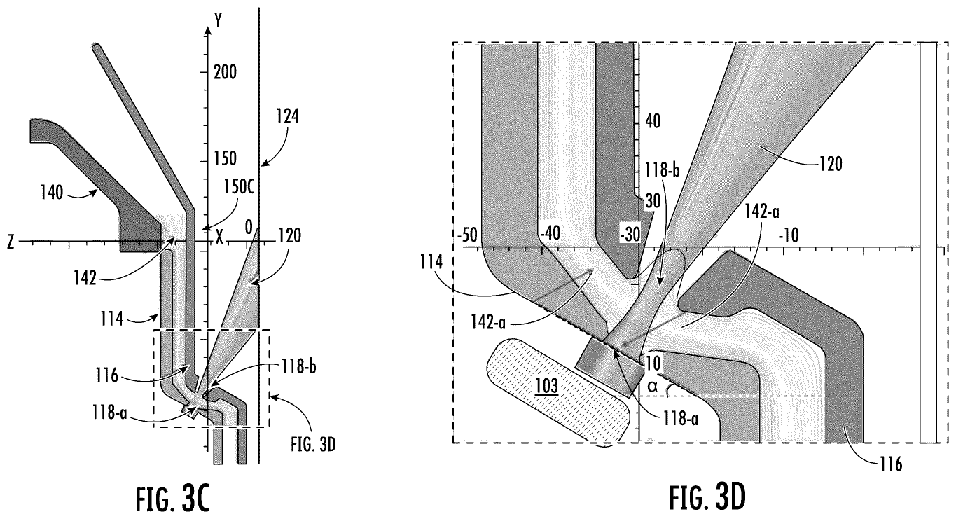

FIG. 3A shows a computer simulation in side cross-sectional view of a variant of an extraction assembly of FIG. 2A, during one scenario of ion beam extraction, showing ions and electric field lines, in accordance with various embodiments of the disclosure, FIG. 3B shows a computer simulation of the scenario of FIG. 3A, showing secondary electrons. In the example of FIG. 3A, the ion beam 120 is not ideally tuned so that a portion of the ion beam 120 strikes acceleration plate 116. Furthermore, as shown in FIG. 3B, because there is a line-of-sight between the substrate 124 and the grounded ion source envelope, secondary electrons 144 emitted at the substrate surface of substrate 124 travel back toward the plasma chamber as represented by enclosure 140. These modelling results are confirmed by experimental observations where there are traces of the beam strike of an acceleration plate are observed.

FIG. 3C shows a computer simulation in side cross-sectional view of a variant of an extraction assembly of FIG. 2C, during ion beam extraction, in accordance with various embodiments of the disclosure, FIG. 3D shows a close-up view of the arrangement of FIG. 3A. The extraction aperture 118-a and extraction aperture 118-b may be strictly aligned with one another, so that the centers of each of these apertures may lie along a common line. As noted, the screen plate 114 and acceleration plate 116 may be separated by just several millimeters, such as 8 mm. A positive ion beam for angled ion beam 120 may be extracted by electrostatically grounding the plasma chamber 102, as well as the screen plate 114, and then applying a negative potential on the acceleration plate 116 and the substrate 124. In the gap between the screen plate 114 and acceleration plate 116 an electrostatic field 142-a is generated that is oriented in such a fashion that the electric field 142-a pulls the ions from the plasma 103 through the aperture 118-a and accelerates the ions through the aperture 118-b. Once the ions pass through the aperture 118-b, the ions continue on a trajectory toward the substrate 124 in a straight line because the region between the acceleration plate 116 and the substrate 124/insert122 is field free (substrate 124, insert 122, and acceleration plate 116 are coupled at the same potential in this embodiment). As a result, ions striking the substrate surface have an angular distribution centered around a certain angle given by the orientation of the planes of the aperture 118-a and aperture 118-b relative to the normal to the substrate plane (z-axis). For the case shown, the angled sections of the screen plate 114 and of the acceleration plate 116 define aperture planes that are tilted at angle α relative to normal to the substrate surface—therefore the mean incidence angle on the wafer will be 90°—α.

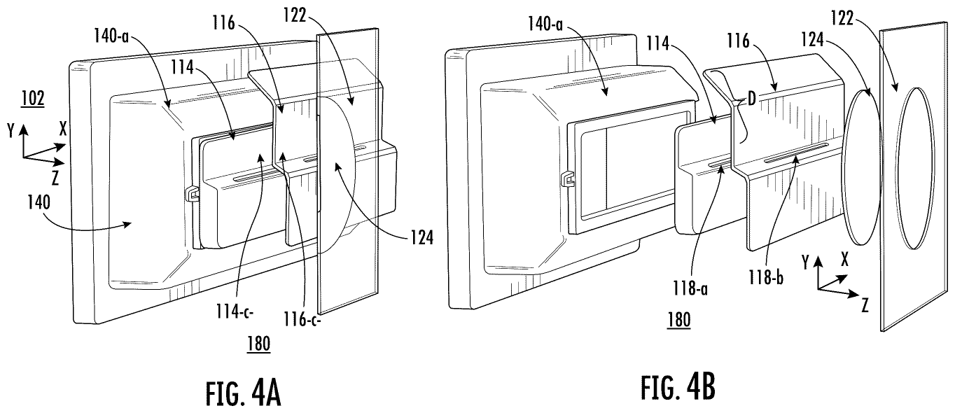

FIGS. 4A-6C show an arrangement of extraction optics and constituent parts of the extraction optics according to an embodiment of the disclosure. In particular, FIG. 4A shows a perspective view of an extraction optics 180, in accordance with embodiments of the present disclosure, while FIG. 4B shows an exploded view of the extraction optics 180 of FIG. 4A. As noted, in operation, the acceleration plate 116 is maintained at a lower potential than the screen plate 114, to extract and accelerate positive ions through the aperture 118-a and aperture 118-b. As noted, these two apertures may be arranged mutually parallel to one another and aligned with one another so that parallel and perfectly once an ion beam is extracted the ion beam will propagate in a straight line. In this embodiment, the bending of the acceleration plate 116 to align next to the angled side 140-a of enclosure 140 provides more space and allows efficient pumping of etch byproducts in the space between the substrate 124 and the acceleration plate 116. Note that in this embodiment, the insert 122 forms a halo structure that surrounds the substrate 124 and is coplanar with substrate 124.

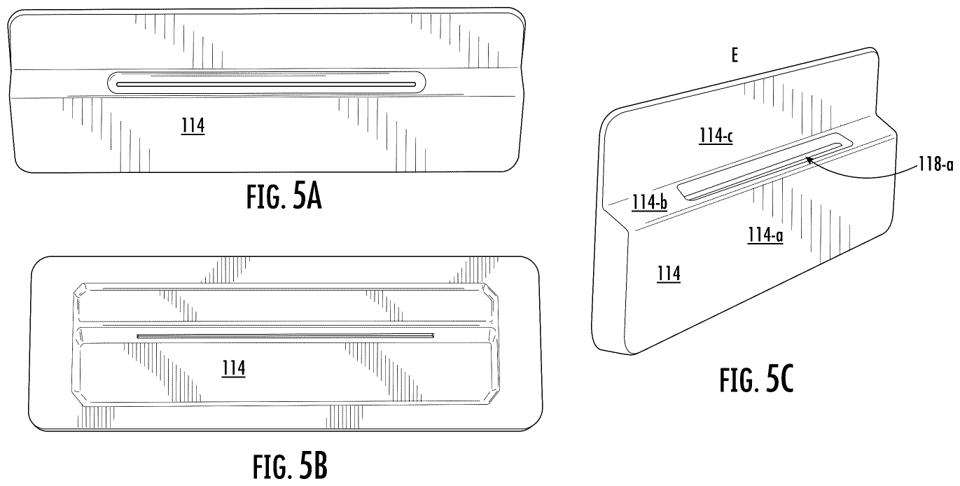

FIG. 5A shows a top tilted view of a screen plate 114, in accordance with some embodiments, FIG. 5B shows a bottom tilted view of the screen plate of FIG. 5A, and FIG. 5C shows a top perspective view of the screen plate of FIG. 5A. FIG. 6A shows a top tilted view of an acceleration plate 116, in accordance with some embodiments, FIG. 6B shows a bottom tilted view of the acceleration plate of FIG. 6A, and FIG. 6C shows a top perspective view of the acceleration plate of FIG. 6A.

In this embodiment, the mutual arrangement of screen plate 114 and acceleration plate 116 in the extraction optics 180 may be as follows. The screen plate 114 is disposed immediately adjacent to the side of the plasma chamber 102, and is fastened to the enclosure 140. The screen plate 114 has a first portion 114-a, disposed away from the plasma chamber 102, an angled portion 114-b that contains a screen aperture 118-a, to extract an angled ion beam towards a first end E of the extraction assembly, and a second portion 114-c, along an edge of the angled portion 114-b, that is, the part adjacent to the enclosure 140 of the plasma chamber 102. The acceleration plate 116 has a middle portion M that includes a first section 116-a and a first angled section 116-b that contains the aperture 118-b, where the middle portion M is shaped according to an outer surface of the screen plate 114. The acceleration plate 116 also has a second section 116-c that extends over the second portion 114-c, as shown in FIG. 4A. The acceleration plate 116 also has a second angled section 116-d that is disposed adjacent to the second section 116-c and is angled toward the enclosure 140 of the plasma chamber 102. In the embodiment of FIGS. 4A-6C, as well as the aforementioned embodiments, including the examples of FIGS. 2A-3D, the acceleration plate will generally include a distal portion formed from a combination of the second section and/or second angled section that serves to at least partially screen the ion beam 120 from electric fields generated in the extraction assembly. Moreover, the distal portion may exhibit a distal end E_{D} that extends beyond an end E_{A} of the screen plate (see FIG. 4B).

In additional embodiments of the disclosure, a distal portion of the acceleration plate may be arranged as a separate part from the middle portion of the acceleration plate. FIG. 6D shows a top tilted view of an acceleration plate 616, in accordance with additional embodiments. The acceleration plate 616 may be arranged similarly to acceleration plate 116, with like parts labeled the same. A difference is that the acceleration plate 616 includes a distal portion represented by a second angled section 616-d, where the distal portion is arranged as a separate part from the middle portion M. Thus, the acceleration plate 616 is actually arranged as at least two separate parts. Note that the middle portion M and the second angled section 616-d may be biased at the same acceleration potential, so that the electrostatic confinement of acceleration plate 616 will be similar to the electrostatic confinement provided by acceleration plate 116. An advantage of this embodiment is in the fabrication the acceleration plate 616, where fabrication/machining of the two parts of acceleration plate 616 is simpler than the fabrication of acceleration plate 116, which plate may be formed from a single piece, for example.

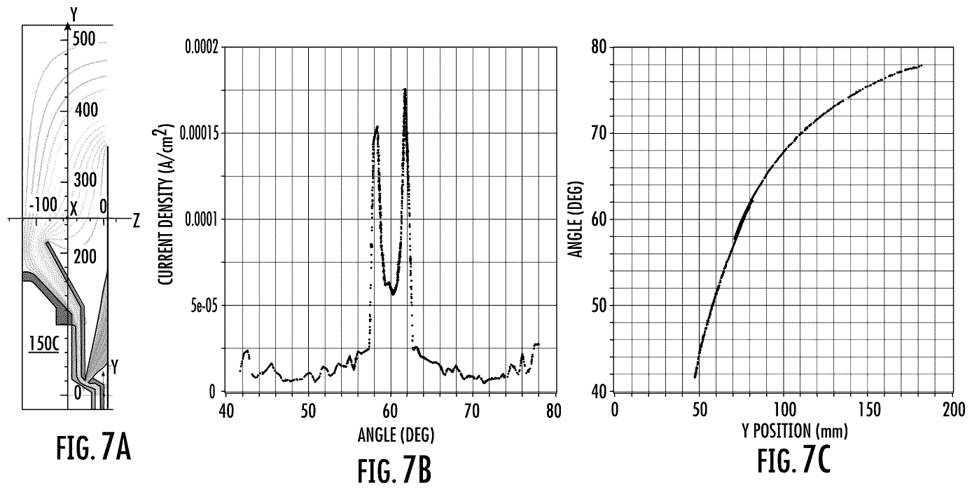

FIG. 7A shows a computer simulation in side cross-sectional view of a variant of an extraction assembly of FIG. 2C, during ion beam extraction, in accordance with various embodiments of the disclosure. FIG. 7B is a graph showing the ion beam current density as a function of beam angle (the ion angular distribution or IAD) for the scenario of FIG. 7A, while FIG. 7C is a graph showing the ion beam angle as a function of position on a substrate for the scenario of FIG. 7A. The beam current conditions are for a nominal 60 angle for the angled section of the extraction assembly, and a 1.4 kV extraction voltage. The IAD is centered about 60 degrees, indicating that the ion beam has not been perturbed by leaking electrostatic fields. Moreover, the beam current is concentrated just between 58 degrees to 62 degrees. The emissivity curve of FIG. 7C shows a divergent beam with the divergence varying monotonically from 45° to 78°.

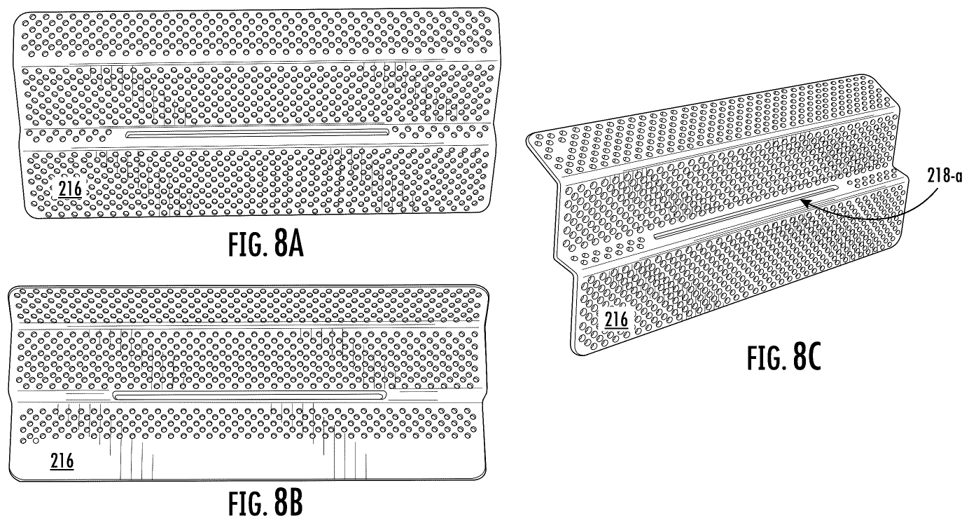

Note that in accordance with various embodiments, the gap between the screen plate 114 and acceleration plate 116 is on the order of few millimeters and therefore is difficult to evacuate during processing. As a result the local pressure may be higher in the gap, and thus prone to glitch generation. This problem is addressed in another embodiment as shown in FIGS. 8A-8C. In particular, FIG. 8A shows a top tilted view of another acceleration plate, acceleration plate 216, in accordance with some embodiments. FIG. 8B shows a bottom tilted view of the acceleration plate 216 of FIG. 8A, while FIG. 8C shows a top perspective view of the acceleration plate 216 of FIG. 8A. In this example, the acceleration plate 216 may be shaped similarly to acceleration plate 116 as a whole, except in this case the acceleration plate 216 is not a continuous plate, rather is perforated. In this fashion the acceleration plate 216 fulfills the intended electrostatic role acting as ion puller and accelerator, while at the same time allowing pumping of the gap between the screen plate 114 and acceleration plate 216, thus reducing glitching probability.

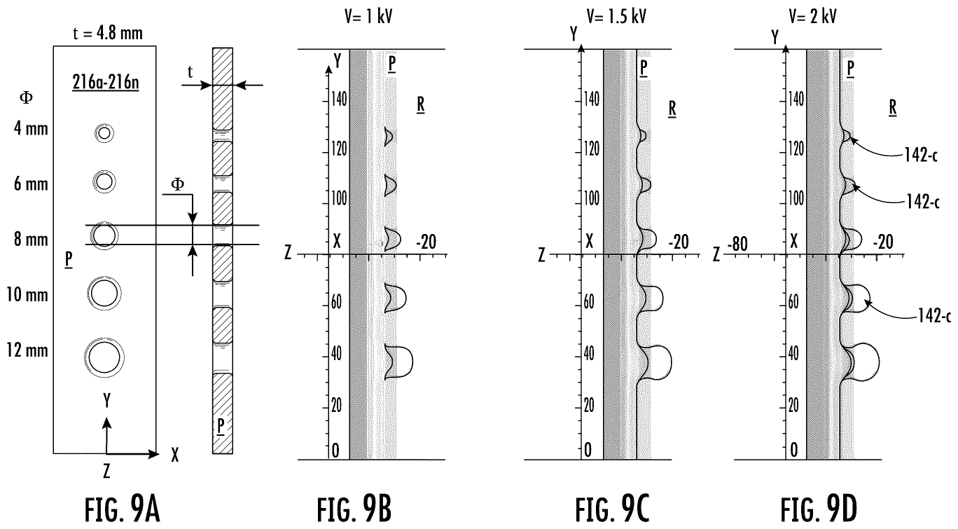

FIG. 9A shows a top and side view of exemplary perforated plate configurations. FIG. 9B depicts a composite view of the perforated plate configurations and the simulation of associated electric fields under a first extraction voltage. In this figure and other figures, the plate P represents the acceleration plate. FIG. 9C depicts a composite view of the perforated plate configurations and associated electric fields under a second extraction voltage. FIG. 9D depicts a composite view of the perforated plate configurations and associated electric fields under a third extraction voltage. Note that in accordance with the embodiment of FIGS. 8A-8C, the acceleration plate 216 may be configured with a uniform hole distribution of identical holes having the same diameter, all over the acceleration plate surface except the region of the aperture 218-a where the ion beam has to be extracted. In accordance with the present embodiments, hole diameters and plate thickness may be chosen in such a fashion that no leak of electrostatic field lines occurs in the beam propagation region. As can be seen in FIGS. 9B-9D for a plate thickness of 4.8 mm, no leakage of electrostatic field lines 142-c into the beam propagation region R occurs for holes having diameter below 6 mm for highest employed voltage of 2 kV.

FIG. 9E depicts a composite view of the perforated plate configurations and associated electric field under a first plate thickness at a given extraction voltage, in this case, 2 kV. FIG. 9F depicts a composite view of the perforated plate configurations and associated electric field under a second plate thickness at the given extraction voltage. FIG. 9G depicts a composite view of the perforated plate configurations and associated electric field under a first plate thickness at the given extraction voltage. As seen in these figures, for a thickness t of 7.2 mm no electrostatic field lines 142-c protrude through holes having hole diameters Φ below 8 mm. Generally, protrusion depth P_{D} is proportional with the voltage between the plates and invers proportional with the hole aspect ratio (t/Φ) , wherein P_{D}˜V×(t/Φ) ,

The hole diameter-plate thickness combination as well as plate transparency (hole density per unit surface area) may be chosen based on considerations of field leaking, plate weight and structural strength, and vacuum conductance.

Another salient aspect is blending/chamfering the holes edges. Well known is the fact that at sharp edges the electric field is enhanced thus increasing the probability of arcing. In the present embodiments, a 2 mm blending radius is used to fabricate the holes. Computer simulations of the use of such holes with the 2 mm blending radius shows the electrostatic stress is roughly ten times lower than maximum accepted values for electrostatic stress in vacuum.

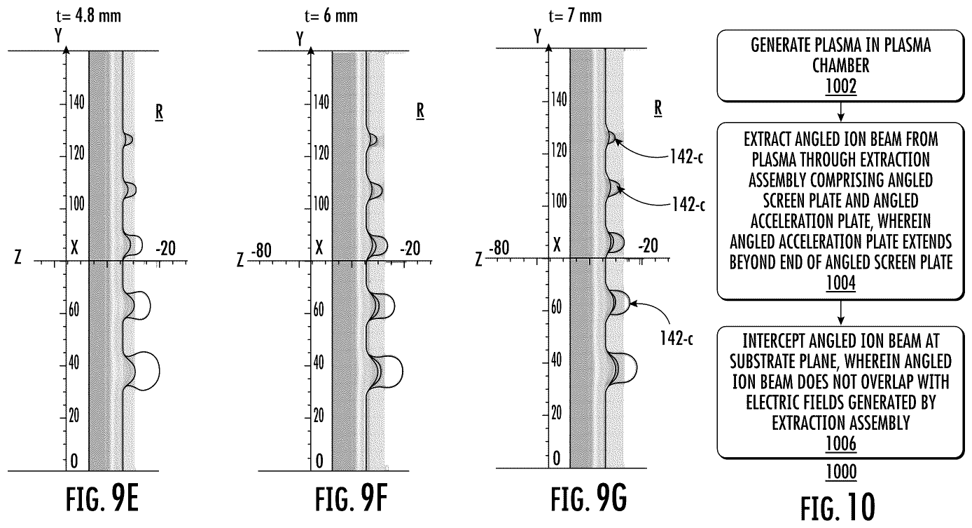

FIG. 10 depicts an exemplary process flow 1000. At block 1002, a plasma is generated in a plasma chamber. At block 1004,

An angled ion beam is extracted from the plasma through an extraction assembly comprising angled screen plate and angled acceleration plate, wherein an angled acceleration plate extends beyond the end of the angled screen plate.

At block 1006 the angled ion beam is intercepted at a substrate plane, wherein the angled ion beam does not overlap with electric fields generated by the extraction assembly

In sum, the present embodiments provide novel apparatus and extraction assemblies that are generally arranged with one or more extraction plates having novel shapes for acceleration plates, in particular.

For the sake of convenience and clarity, terms such as “top,” “bottom,” “upper,” “lower,” “vertical,” “horizontal,” “lateral,” and “longitudinal” are used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present embodiments provide at least the following advantages. As a first advantage, the novel shaping and relative arrangement of the combination of the components of the extraction assemblies of the present embodiments provides the ability to extraction high angle ion beams without electric field interference. This advantage leads to high angle ion beams having better control of angular spread, for example. Another advantage provided by the present embodiments is the ability to efficiently pump gaseous species in high angle ion beam configurations, using the novel acceleration plate perforations.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A processing system, comprising:
a plasma chamber operable to generate a plasma; and
an extraction assembly, arranged along a side of the plasma chamber, the extraction assembly comprising:
a screen plate, disposed immediately adjacent to the side of the plasma chamber, the screen plate having an angled portion that comprises a screen aperture, to extract an angled ion beam towards a first end of the extraction assembly; and
an acceleration plate, disposed outside of the screen plate, the acceleration plate having a middle portion that is shaped according to an outer surface of the screen plate,
wherein the acceleration plate comprises an acceleration aperture, aligned with the screen aperture, and
wherein the acceleration plate comprises a distal portion adjacent to the middle portion, the distal portion having a distal end that extends beyond an end of the screen plate.

2. The processing system of claim 1, wherein the outer surface of the screen plate has a staggered structure, the staggered structure comprising:
a first portion, disposed away from the plasma chamber, and disposed along a first edge of the angled portion; and
a second portion, disposed along a second edge of the angled portion, and immediately adjacent to the plasma chamber.

3. The processing system of claim 2, wherein the acceleration plate comprises:
has a first section, aligned over the first portion of the screen plate;
a first angled section, having a first edge, adjacent to the first section, and containing the acceleration aperture; and
a second section, having an inner edge adjacent to a second edge of the angled section, and extending over the second portion of the screen plate and beyond an end of the second portion.

4. The processing system of claim 3, wherein the acceleration plate further comprises a second angled section, disposed adjacent to an outer edge of the second section, and angled toward the plasma chamber.

5. The processing system of claim 4, wherein the plasma chamber comprises an enclosure having an angled side region, and wherein the second angled section is angled to match the angled side region of the plasma chamber.

6. The processing system of claim 1, further comprising a process chamber, disposed along the side of the plasma chamber, wherein the acceleration plate is disposed within the process chamber.

7. The processing system of claim 6, further comprising a substrate stage, disposed within the process chamber, the substrate stage comprising a drive, arranged to move the substrate stage along at least a first scan direction with respect to the extraction assembly.

8. The processing system of claim 7, wherein the screen aperture and the acceleration aperture are elongated along a aperture axis that extends perpendicularly to the first scan direction.

9. The processing system of claim 7,
wherein the substrate stage defines a substrate plane that lies parallel to the first scan direction, and
wherein the extraction assembly is arranged to extract an ion beam from the plasma chamber and direct the ion beam to the substrate plane along a beam trajectory that forms an angle of 40 degrees or more with respect to a perpendicular to the substrate plane.

10. The processing system of claim 9, wherein the extraction assembly is arranged to generate an ion angular distribution of less than 10 degrees.

11. The processing system of claim 9, wherein the extraction assembly is arranged to generate a set of electric field lines when the ion beam is extracted from the plasma chamber, and wherein the electric field lines do not overlap with the ion beam.

12. The processing system of claim 1, further comprising a bias voltage supply, arranged to bias the acceleration plate at an acceleration potential with respect to the plasma chamber.

13. The processing system of claim 12, wherein the bias voltage supply is further coupled to bias the substrate holder at the acceleration potential.

14. The processing system of claim 12, wherein
wherein the distal portion is arranged as a separate part from the middle portion, and wherein the middle portion and the distal portion are biased at the acceleration potential.

15. The processing system of claim 1, wherein the acceleration plate is perforated, comprising a plurality of holes.

16. The processing system of claim 14, wherein the acceleration plate comprises a thickness t and the plurality of holes comprise a hole diameter Φ wherein a ( t/Φ)≥1.

17. The processing system of claim 14, wherein the plurality of holes have a chamfered shape.

18. A method of processing a substrate, comprising:
generating a plasma in a plasma chamber; and
extracting an angled ion beam from the plasma chamber through an extraction assembly, comprising:
a screen plate, having an angled portion that comprises a screen aperture, to extract the angled ion beam towards a first end of the extraction assembly; and
an acceleration plate, having a middle portion that is shaped according to an outer surface of the screen plate, and having an acceleration aperture, aligned with the screen aperture, and
directing the angled ion beam to the substrate, wherein the angled ion beam does not overlap a set of electric filed lines that are generated by the extraction assembly.

19. The method of claim 18, wherein the acceleration plate comprises:
a first section, aligned over a first portion of the screen plate;
a first angled section, having a first edge, adjacent to the first section, and containing the angled aperture; and
a second section, having an inner edge adjacent to a second edge of the angled section, and extending over a second portion of the screen plate and beyond an end of the second portion.
